(19) United States
(12) Patent Application Publication
(10) Pub. No.: US 2024/0212756 A1
(43) Pub. Date: Jun. 27, 2024

(54) VERTICAL TYPE MEMORY DEVICE

(71) Applicant: Samsung Electronics Co., Ltd., Suwon-si (KR)

(72) Inventors: Hyunmook Choi, Suwon-si (KR); Jihong Kim, Suwon-si (KR)

(21) Appl. No.: 18/390,258

(22) Filed: Dec. 20, 2023

(30) Foreign Application Priority Data
Dec. 26, 2022 (KR) 10-2022-0185021

(51) Int. Cl. G11C 16/04; H01L 25/065; H10B 41/10; H10B 41/27; H10B 41/35; H10B 43/10; H10B 43/27; H10B 43/35; H10B 80/00

(52) U.S. Cl. CPC G11C 16/0483; H01L 25/0652; H10B 41/10; H10B 41/27; H10B 41/35; H10B 43/10; H10B 43/27; H10B 43/35; H10B 80/00; H01L 2225/06506

(57) ABSTRACT

A vertical type memory device includes a first pillar structure in a channel hole inside a word line mold, and a second pillar structure in a string select line hole overlapping the channel hole inside a string select line mold. The first pillar structure includes a first gate insulating layer and a cell channel layer on an inner wall of the channel hole, a variable resistance layer on one side of the cell channel layer, a first filling insulating layer filling the channel hole, and a connection pad in an upper portion of the first filling insulating layer. The second pillar structure includes a second gate insulating layer on an inner wall of the string select line hole, a select channel layer on one side of the second gate insulating layer, and a second filling insulating layer filling the string select line hole on the select channel layer.

### CROSS-REFERENCE TO RELATED APPLICATION(S)

This application is based on and claims priority under 35 U.S.C. § 119 to Korean Patent Application No. 10-2022-0185021, filed on Dec. 26, 2022, in the Korean Intellectual Property Office, the disclosure of which is incorporated by reference herein in its entirety.

### BACKGROUND

The inventive concept relates to a memory device, and more particularly, to a vertical type memory device.

In electronic systems requiring data storage, memory devices capable of storing high-capacity data are required. Accordingly, a method of increasing data storage capacity of memory devices has been researched. For example, as one of the methods of increasing data storage capacity of memory devices, a vertical type memory device including three-dimensionally arranged memory cells (or memory cell strings), instead of two-dimensionally arranged memory cells, has been proposed.

### SUMMARY

The inventive concept provides a vertical type memory device in which pillar structures constituting a memory cell string are easily connected.

According to an aspect of the inventive concept, there is provided a vertical type memory device including a word line mold on a substrate, a first pillar structure in a channel hole inside the word line mold, a string select line mold on the word line mold and the first pillar structure, and a second pillar structure in a string select line hole overlapping the channel hole inside the string select line mold.

The first pillar structure includes a first gate insulating layer and a cell channel layer on an inner wall of the channel hole, a variable resistance layer on one side of the cell channel layer at a height lower than a height of the cell channel layer in the channel hole, relative to an upper surface of the substrate, a first filling insulating layer filling the channel hole, and a connection pad in an upper portion of the first filling insulating layer inside the channel hole.

The second pillar structure includes a second gate insulating layer on an inner wall of the string select line hole, a select channel layer on one side of the second gate insulating layer within the string select line hole and connected to the connection pad, and a second filling insulating layer filling the string select line hole on the select channel layer.

According to another aspect of the inventive concept, there is provided a vertical type memory device including a word line mold on a substrate, a first pillar structure in a channel hole inside the word line mold, a string select line mold on the word line mold and the first pillar structure, and a second pillar structure in a string select line hole overlapping the channel hole inside the string select line mold in a vertical direction.

The first pillar structure includes a first gate insulating layer and a cell channel layer on an inner wall of the channel hole, a variable resistance layer on one side of the cell channel layer at a height lower than a height of the cell channel layer in the channel hole, a first filling insulating layer filling the channel hole, a recess hole formed to be lower than a surface of the first gate insulating layer and the cell channel layer, and a connection pad filling the recess hole.

The second pillar structure includes a second gate insulating layer on an inner wall of the string select line hole, a select channel layer on one side of the second gate insulating layer within the string select line hole and connected to the connection pad, and a second filling insulating layer filling the string select line hole on the select channel layer.

According to another aspect of the inventive concept, there is provided a vertical type memory device including a word line mold on a substrate, a first pillar structure in a channel hole inside the word line mold, a string select line mold on the word line mold and the first pillar structure, and a second pillar structure in a string select line hole overlapping the channel hole inside the string select line mold in a vertical direction.

The first pillar structure includes a first gate insulating layer and a cell channel layer on an inner wall of the channel hole, a variable resistance layer on one side of the cell channel layer at a height lower than a height of the cell channel layer in the channel hole, a first filling insulating layer filling the channel hole, a recess hole formed to be lower than a surface of the first gate insulating layer and the cell channel layer, and a connection pad on an inner wall of the recess hole and an upper portion of the recess hole.

The second pillar structure includes a second gate insulating layer on an inner wall of the string select line hole, a select channel layer on one side of the second gate insulating layer within the string select line hole and connected to the connection pad, and a second filling insulating layer filling the string select line hole on the select channel layer.

### BRIEF DESCRIPTION OF THE DRAWINGS

Embodiments will be more clearly understood from the following detailed description taken in conjunction with the accompanying drawings, wherein like reference numerals (when used) indicate corresponding elements throughout the several views, and in which:

FIG. 1 is a block diagram of an example vertical type memory device, according to an embodiment;

FIG. 2 is an equivalent circuit diagram of an example memory cell array of a vertical type memory device, according to an embodiment;

FIG. 3 is a plan view of an example memory cell array of a vertical type memory device, according to an embodiment;

FIG. 4 is a cross-sectional view of at least a portion of an example memory cell array of a vertical type memory device, according to an embodiment;

FIG. 5A is an enlarged view of the upper portion of the example memory cell array shown in FIG. 4;

FIG. 5B is an enlarged view of the lower portion of the example memory cell array shown in FIG. 4;

FIG. 6 is a cross-sectional view of an example memory cell array of a vertical type memory device, according to an embodiment;

FIG. 7 is an enlarged view of a portion of the example memory cell array shown in FIG. 6;

FIGS. 8 to 19 are cross-sectional views illustrating intermediate processes in an example method of manufacturing a memory cell array of a vertical type memory device, according to one or more embodiments;

FIG. 20 is a cross-sectional view illustrating at least a portion of an example vertical type memory device, according to an embodiment;

FIG. 21 is a view schematically illustrating at least a portion of an example electronic system including a vertical type memory device, according to an embodiment;

FIG. 22 is a perspective view schematically illustrating at least a portion of an example electronic system including a vertical type memory device, according to an embodiment; and

FIG. 23 is a cross-sectional view illustrating example semiconductor packages, according to an embodiment.

### DETAILED DESCRIPTION OF THE EMBODIMENTS

Hereinafter, embodiments of the inventive concept are described in detail with reference to the accompanying drawings. Like reference numerals are used for like components in the accompanying drawings, and redundant descriptions thereof are omitted.

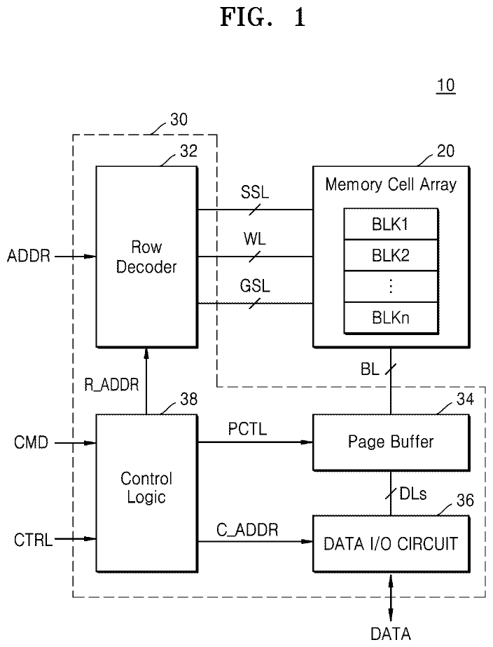

FIG. 1 is a block diagram of at least a portion of an example vertical type memory device 10, according to one or more embodiments.

In an embodiment, the vertical type memory device 10 may include a memory cell array 20 and a peripheral circuit 30 operatively coupled with the memory cell array 20. The memory cell array 20 includes a plurality of memory cell blocks BLK1, BLK2, . . . , BLKn, where n is an integer greater than one. Each of the memory cell blocks BLK1, BLK2, ..., BLKn may include a plurality of memory cells. The memory cell blocks BLK1, BLK2, . . . , BLKn may be connected to the peripheral circuit 30 through one or more bit lines BL, one or more word lines WL, one or more string select lines SSL, and one or more ground select lines GSL.

In one or more embodiments, the peripheral circuit 30 may include a row decoder 32, a page buffer 34, a data input/output (I/O) circuit 36, and a control logic 38. Although not explicitly shown in FIG. 1 (but implied), the peripheral circuit 30 may further include one or more of an I/O interface, a column logic, a voltage generator, a pre-decoder, a temperature sensor, a command decoder, an address decoder, an amplifier circuit, and the like.

The memory cell array 20 may be connected to the page buffer 34 through a bit line BL and may be connected to the row decoder 32 through a word line WL, a string select line SSL, and a ground select line GSL. In the memory cell array 20, each of the memory cells included in the memory cell blocks BLK1, BLK2, . . . , BLKn may be a flash memory cell, although embodiments of the present disclosure are not limited thereto. The memory cell array 20 May include a 3D memory cell array.

The 3D memory cell array may include a plurality of NAND strings, and each NAND string may include a plurality of memory cells respectively connected to a plurality of word lines WL vertically stacked on a substrate.

The peripheral circuit 30 may receive an address ADDR, a command CMD, and a control signal CTRL from the outside of the memory device 10, and may transmit and receive data DATA to and from a device outside the memory device 10. As used herein, the terms “outside device” or “outside signal” are intended to broadly refer to a device, circuit, block, module and/or signal that resides externally (i.e., outside of a functional or physical boundary) with respect to a given circuit, block, module, or device.

In response to the address ADDR from the outside, the row decoder 32 may select at least one of the memory cell blocks BLK1, BLK2, . . . , BLKn, and may select the word line WL, the string select line SSL, and the ground select line GSL of the selected memory cell block. The row decoder 32 may transfer a voltage for performing a memory operation to the word line WL of the selected memory cell block.

The page buffer 34 may be connected to the memory cell array 20 through the bit line BL. During a program (i.e., write) operation, the page buffer 34 may operate as a write driver to apply a voltage according to the data DATA to be stored in the memory cell array 20 to the bit line BL, and during a read operation, the page buffer 34 may operate as a sense amplifier to sense the data DATA stored in the memory cell array 20. The page buffer 34 may operate according to a control signal PCTL provided from the control logic 38.

The data input/output circuit 36 may be connected to the page buffer 34 through one or more data lines DLs. During a program operation, the data I/O circuit 36 may receive data DATA from a memory controller (not explicitly shown) and provide program data DATA to the page buffer 34 based on a column address C_ADDR provided from the control logic 38.

During a read operation, the data I/O circuit 36 may provide the read data DATA stored in the page buffer 34 to the memory controller based on the column address C_ADDR provided from the control logic 38.

The data I/O circuit 36 may transfer an input address or command to the control logic 38 or the row decoder 32. Although not explicitly shown, the peripheral circuit 30 may further include an electrostatic discharge (ESD) circuit and a pull-up/pull-down driver.

The control logic 38 may receive a command CMD and a control signal CTRL from the memory controller. The control logic 38 may provide the row address R_ADDR to the row decoder 32 and the column address C_ADDR to the data I/O circuit 36.

The control logic 38 may generate various internal control signals used in the memory device 10 in response to the control signal CTRL. For example, the control logic 38 may adjust voltage levels provided to the word line WL and the bit line BL when a memory operation, such as a program operation or an erase operation, is performed.

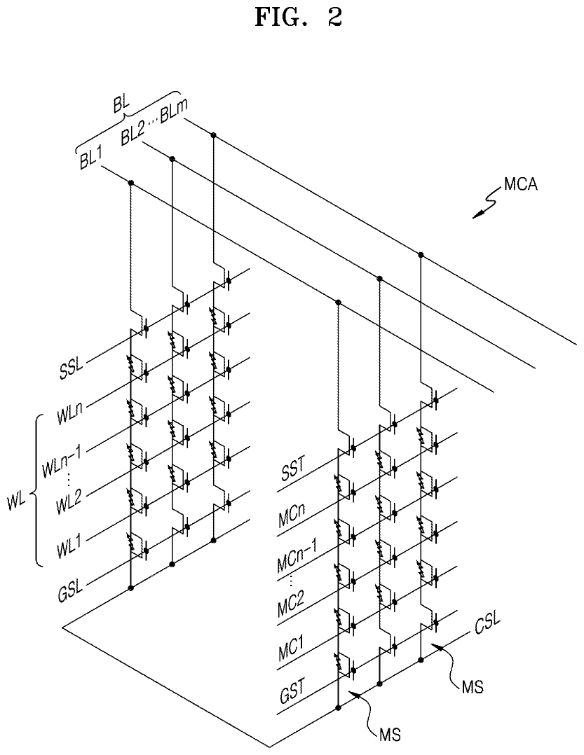

FIG. 2 is an equivalent circuit diagram of at least a portion of an example memory cell array MCA of a vertical type memory device, according to one or more embodiments.

In an embodiment, the memory cell array MCA (e.g., 20 in FIG. 1) may include a plurality of memory cell strings MS. The memory cell array MCA may include a plurality of bit lines BL (BL1, BL2, . . . , BLm, where m is an integer greater than one), a plurality of word lines WL (WL1, WL2, . . . , WLn-1, WLn, where n is an integer greater than one), at least one string select line SSL, at least one ground select line GSL, and a common source line CSL. The number, m, of bit lines BL may be different than the number, n, of word lines WL, although it is similarly contemplated that n and m may be the same in some embodiments.

The memory cell strings MS may be formed between the plurality of bit lines BL (BL1, BL2, . . . , BLm) and the common source line CSL. Although FIG. 2 illustrates a case in which each of the memory cell strings MS includes one string select line SSL, the inventive concept is not limited thereto. For example, each of the memory cell strings MS may include two string select lines SSL.

Each of the memory cell strings MS may include a string select transistor SST, a ground select transistor GST, and a plurality of memory cell transistors MC1, MC2, . . . , MCn-1, MCn. A drain region of the string select transistor SST may be connected to a corresponding one of the bit lines BL (BL1, BL2, . . . , BLm), and a source region of the ground select transistor GST may be connected to the common source line CSL. The common source line CSL may be a region to which source regions of a plurality of ground select transistors GST are connected in common.

A gate of the string select transistor SST in each of the memory cell strings MS may be connected to the string select line SSL, and a gate of the ground select transistor GST may be connected to the ground select line GSL. The memory cell transistors MC1, MC2, . . . , MCn-1, MCn may be connected to the word lines WL (WL1, WL2, . . . , WLn-1, WLn), respectively.

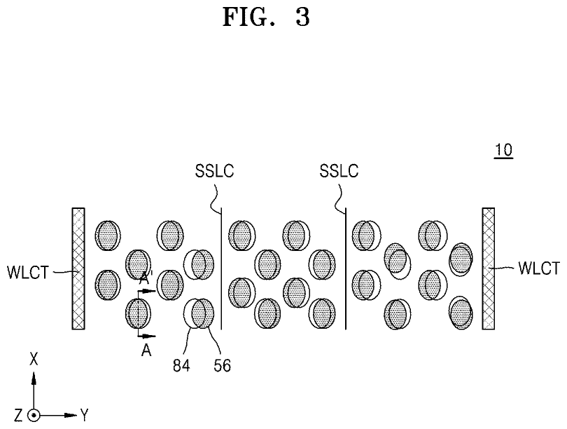

FIG. 3 is a plan view of the memory cell array MCA of the vertical type memory device 10, according to one or more embodiments.

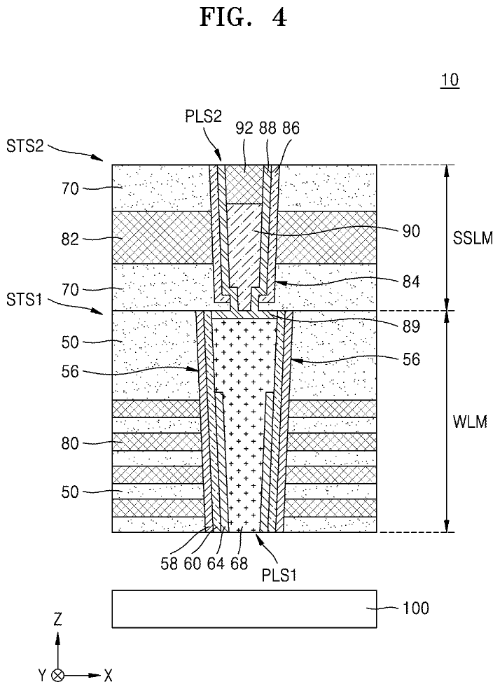

In an embodiment, the memory cell array (e.g., MCA of FIG. 2) of the vertical type memory device 10 may include a word line cut region (WLCT), a string select line cut region (SSLC), a channel hole 56, and a string select line hole 84 as shown in FIG. 3. In the following figures, an X direction (a first horizontal direction) may be a word line (WL in FIG. 2) direction, a Y direction (a second horizontal direction) may be a bit line (BL in FIG. 2) direction perpendicular to the X direction (the first horizontal direction), and a Z direction (a vertical direction) may be a direction perpendicular to a plane parallel to the X direction (the first horizontal direction) and the Y direction (the second horizontal direction), that is, a plane of a substrate (100 in FIG. 4).

The word line cut region WLCT may be an insulating layer region. The word line cut region WLCT may extend in the X direction (the first horizontal direction). The word line (WL in FIG. 2) may extend in the X direction (the first horizontal direction) between the word line cut regions WLCT.

The string select line cut region SSLC may be an insulating layer region. The string select line (SSL in FIG. 2) may extend in the X direction (the first horizontal direction) between the word line cut regions WLCT. Two adjacent string select lines (SSL in FIG. 2) in the second horizontal direction (the Y direction) may be spaced apart from each other with the string select line cut region SSLC therebetween.

The channel holes 56 may be spaced apart from each other between the word line cut regions WLCT and between the string select line cut regions SSLC in the X and Y directions. The channel holes 56 may be portions in which the memory cell transistors (MC1, MC2, . . . , MCn-1, MCn in FIG. 2) and ground select transistors (GST in FIG. 2) of the memory cell string (MS in FIG. 2) are formed.

The string select line holes 84 may be arranged to overlap the channel holes 56, respectively. The term “overlap” or “overlapping,” as used herein, is intended to broadly refer to a first element that intersects with at least a portion of a second element in the vertical direction (Z direction), but does not require that the first and second elements be completely aligned with one another in a horizontal plane (i.e., X and Y directions). Thus, the string select line hole 84 may not exactly overlap the channel hole 56 in the vertical direction (the Z direction). For example, the string select line hole 84 may be shifted and overlap the channel hole 56 in the Y direction (the second horizontal direction), as shown in FIG. 3. The string select line hole 84 May be a portion in which the string select transistor (SST of FIG. 2) of the memory cell string (MS of FIG. 2) is formed.

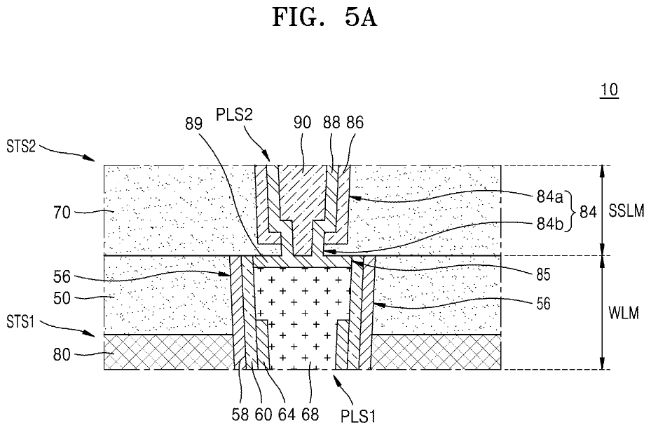

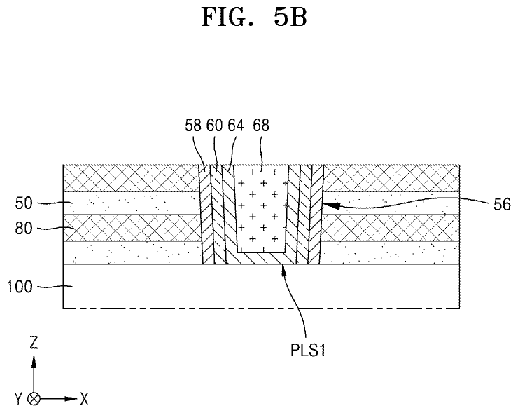

FIG. 4 is a cross-sectional view of at least a portion of an example memory cell array of the vertical type memory device 10 according to an embodiment, FIG. 5A is an enlarged view of the upper portion of the memory cell array 10 shown in FIG. 4, and FIG. 5B is an enlarged view of the lower portion of the memory cell array 10 shown in FIG. 4.

In detail, FIG. 4 is a cross-sectional view taken along line A-A′ of FIG. 3, FIG. 5A is a cross-sectional view illustrating a connection relationship between first and second pillar structures PLS1 and PLS2 of FIG. 4, and FIG. 5B is a cross-sectional view illustrating a connection relationship between the first pillar structure PLS1 and a substrate 100, according to some embodiments. In FIGS. 4, 5A, and 5B, the description given above with reference to FIGS. 1 to 3 is briefly given or omitted.

The vertical type memory device 10 may be formed on the substrate 100. The substrate 100 may include a semiconductor material, for example, a Group IV semiconductor, a Group III-V compound semiconductor, or a Group II-VI oxide semiconductor. For example, the Group IV semiconductor may include silicon (Si), germanium (Ge), or silicon-germanium. The substrate 100 may be provided as a bulk wafer or an epitaxial layer. In another embodiment, the substrate 100 may include a silicon-on-insulator (SOI) substrate or a germanium-on-insulator (GeOI) substrate. It is to be understood, however, that embodiments of the present disclosure are not limited to any material(s) forming the substrate 100.

The vertical type memory device 10 may include a word line mold WLM formed on the substrate 100 and a first pillar structure PLS1 formed in the channel hole 56 inside the word line mold WLM. The term “inside,” as used herein, is intended to be broadly defined as “within a prescribed boundary of,” and does not necessarily mean “covered by” or “enclosed by.” The word line mold WLM may include a first stack structure STS1 including a plurality of cell insulating layers 50 and a first electrode layer 80 located between the cell insulating layers 50.

The first stack structure STS1 may be a structure in which the cell insulating layer 50 and the first electrode layer 80 are sequentially stacked on the substrate 100. Among the cell insulating layers 50, the cell insulating layer 50 located above (an upper cell insulating layer) may be thicker than the cell insulating layer 50 located below (a lower cell insulating layer); that is, the cell insulating layers 50 need not be formed having the same thicknesses relative to one another.

The first electrode layer 80 may be a first gate electrode layer. The first electrode layer 80 may correspond to the word lines WL1, WL2, . . . , WLn-1, and WLn of FIGS. 2 and 3. In FIG. 5B, the first electrode layer 80 formed on a lowermost portion to the substrate 100 may correspond to the ground select line GSL of FIG. 2.

In some embodiments, the cell insulating layer 50 may include silicon oxide, and the first electrode layer 80 may include tungsten, titanium, titanium nitride, tantalum, tantalum nitride, impurity-doped polysilicon, or the like.

The first pillar structure PLS1 may include a first gate insulating layer 58 and a cell channel layer 60 formed on an inner wall of the channel hole 56. As shown in FIG. 5B, the first pillar structure PLS1 may include the first gate insulating layer 58 and the cell channel layer 60 formed on the inner wall of the channel hole 56 and formed on the substrate 100.

The first gate insulating layer 58 and the cell channel layer 60 may be formed inside the channel hole 56. The channel hole 56 may be formed through the first stack structure STS1 in the vertical direction (Z direction). The first stack structure STS1 may be located on both sides of the channel hole 56. The channel hole 56 may expose an upper surface of the substrate 100 as shown in FIG. 5B.

The first gate insulating layer 58 may include at least one of metal oxides, such as silicon oxide, aluminum oxide, and hafnium oxide. The cell channel layer 60 may be a semiconductor layer. For example, the cell channel layer 60 may include polysilicon doped with one or more impurities or polysilicon without impurities.

The first pillar structure PLS1 may include a variable resistance layer 64 within the channel hole 56 formed on one side of the cell channel layer 60 (opposite the first gate insulating layer 58) at a height lower than that of the cell channel layer 60 within the channel hole 56, and a first filling insulating layer 68 filling the channel hole 56. As may be used herein, the term “filling” (“fill” or “filled”), as used herein, is intended to refer to either completely filling a defined space (e.g., channel hole 56) or partially filling the defined space; that is, the defined space need not be entirely filled but may, for example, be partially filled or have voids or other spaces throughout.

The variable resistance layer 64 may be formed inside the cell channel layer 60 at a height lower than an upper portion of the channel hole 56. As shown in FIG. 5B, the variable resistance layer 64 may be formed on the cell channel layer 60 within the channel hole 56. As shown in FIG. 5B, the variable resistance layer 64 may be formed on one side of the cell channel layer 60.

In some embodiments, in the variable resistance layer 64, an electrical path, such as a filament, may be formed by a voltage difference across the variable resistance layer 64 by the first electrode layer 80, and accordingly, the variable resistance layer 64 may include a material having internal resistance that fluctuates. For example, the filament may be formed by oxygen vacancy due to movement of oxygen included in the variable resistance layer 64. Accordingly, the variable resistance layer 64 may be selectively changed to a low resistance state or a high resistance state.

In some embodiments, the variable resistance layer 64 may include a perovskite-based material or a transition metal oxide. The perovskite-based material may include, for example, STO(SrTiO₃), BTO(BaTiO₃), PCMO(Pr_{1-X}Ca_{X}MnO₃), and the like, and the transition metal oxide may include, for example, titanium oxide (TiOx), zirconium oxide (ZrOx), aluminum oxide (AlOx), hafnium oxide (HfOx), tantalum oxide (TaOx), niobium oxide (NbOx), cobalt oxide (CoOx), tungsten oxide (WOx), lanthanum oxide (LaOx), zinc oxide (ZnOx) and the like. These materials may be used alone or in combination of two or more thereof.

In some embodiments, the variable resistance layer 64 may have a single film structure including one or more the above materials or may have a composite film structure in which a plurality of films are stacked. In some embodiments, the variable resistance layer 64 may have a thickness of about 5 nanometers to about 20 nanometers but is not limited thereto. Because the first pillar structure PLS1 includes the variable resistance layer 64, the vertical type memory device 10 according to the inventive concept may be referred to as a variable resistance vertical type memory device. The vertical type memory device 10 of the inventive concept may be a nonvolatile variable resistance vertical type memory device.

The first filling insulating layer 68 may not entirely fill the channel hole 56 on the variable resistance layer 64 and the cell channel layer 60. An upper surface of the first filling insulating layer 68 may be lower than an upper surface of the channel hole 56. The upper surface of the first filling insulating layer 68 may be lower than upper surfaces of the cell channel layer 60 and the first gate insulating layer 58. In some embodiments, the first filling insulating layer 68 may include silicon oxide, silicon nitride, silicon oxynitride (SiON), or combinations thereof.

The first pillar structure PLS1 may include a connection pad 89 formed on an upper portion of the first filling insulating layer 68 inside the channel hole 56. As shown in FIG. 5A, the connection pad 89 may fill a recess hole 85 located on the first filling insulating layer 68 inside the channel hole 56.

The connection pad 89 may be referred to as an intermediate pad. Both sides of the connection pad 89 may contact the cell channel layer 60 within the channel hole 56. The connection pad 89 may include polysilicon doped with impurities or without impurities.

The vertical type memory device 10 may include a string select line mold SSLM formed on the word line mold WLM and the first pillar structure PLS1, and a second pillar structure PLS2 formed in the string select line hole 84 overlapping the channel hole 56 inside the string select line mold SSLM.

As shown in FIG. 5A, the string select line hole 84 is shown to overlap a central portion of the channel hole 56, that is, a central portion of the connection pad 89 in the Z direction (the vertical direction), but the inventive concept is not limited thereto. In the inventive concept, the second pillar structure PLS2 may be easily connected to the first pillar structure PLS1 even if the second pillar structure PLS2 is shifted in the X direction or the Y direction from the central portion of the string select line hole 84 by including the connection pad 89. In some embodiments, a diameter of the string select line hole 84 may be less than a diameter of the channel hole 56 in the X and Y directions, although embodiments of the present inventive concept are not limited thereto.

The string select line mold SSLM may include a second stack structure STS2 including a plurality of string select insulating layers 70 and a second electrode layer 82 located between the string select insulating layers 70. In FIG. 4, two string select insulating layers 70 and one second electrode layer 82 are shown, but the inventive concept is not limited thereto.

The second electrode layer 82 may be a second gate electrode layer. The second electrode layer 82 may correspond to the string select line SSL of FIGS. 2 and 3. In some embodiments, the string select insulating layers 70 may include silicon oxide, and the second electrode layer 82 may include tungsten, titanium, titanium nitride, tantalum, tantalum nitride, polysilicon doped with impurities, or the like.

The second pillar structure PLS2 may include a second gate insulating layer 86 formed on an inner wall of the string select line hole 84 and a select channel layer 88 formed on one side of the second gate insulating layer 86 and connected to the connection pad 89 within the string select line hole 84.

The second gate insulating layer 86 and the select channel layer 88 may be formed inside the string select line hole 84. The second gate insulating layer 86 may be apart from the connection pad 89. The string select line hole 84 may be formed through the second stack structure STS2. The second stack structure STS2 may be located on both sides of the string select line hole 84.

As shown in FIG. 5A, the string select line hole 84 may include a first string select line hole 84a located on an upper side and a second string select line hole 84b located below the first string select line hole 84a and having a smaller diameter. The second gate insulating layer 86 may be formed on an inner wall of the first string select line hole 84a.

As shown in FIG. 5A, the select channel layer 88 may be formed on the second gate insulating layer 86 inside the first string select line hole 84a. The select channel layer 88 may be connected to a portion of an upper surface of the connection pad 89.

The second gate insulating layer 86 may include, for example, at least one of metal oxides, such as silicon oxide, aluminum oxide, and hafnium oxide. The select channel layer 88 may be a semiconductor layer. The select channel layer 88 may include, for example, polysilicon doped with one or more impurities or polysilicon without impurities. The select channel layer 88 may be integrated with the connection pad 89. The select channel layer 88 may include the same material as that of the connection pad 89.

As shown in FIG. 4, the second pillar structure PLS2 may include a second filling insulating layer 90 filling the string select line hole 84 on the select channel layer 88. The second filling insulating layer 90 may not entirely fill the string select line hole 84 on the select channel layer 88.

An upper surface of the second filling insulating layer 90 may be lower than an upper surface of the string select line hole 84. The upper surface of the second filling insulating layer 90 may be lower than upper surfaces of the select channel layer 88 and the second gate insulating layer 86. In some embodiments, the second filling insulating layer 90 may include silicon oxide, silicon nitride, silicon oxynitride (SiON), or combinations thereof.

The second pillar structure PLS2 may include a bit line pad 92 contacting the select channel layer 88 inside the string select line hole 84 on an upper surface of the second filling insulating layer 90. The bit line pad 92 may correspond to the bit line BL of FIG. 2. Both sidewalls of the bit line pad 92 may contact the select channel layer 88.

Because the vertical type memory device 10 as described above includes the first pillar structure PLS1 including the connection pad 89, the first pillar structure PLS1 may be easily connected to the second pillar structure PLS2 by using the connection pad 89.

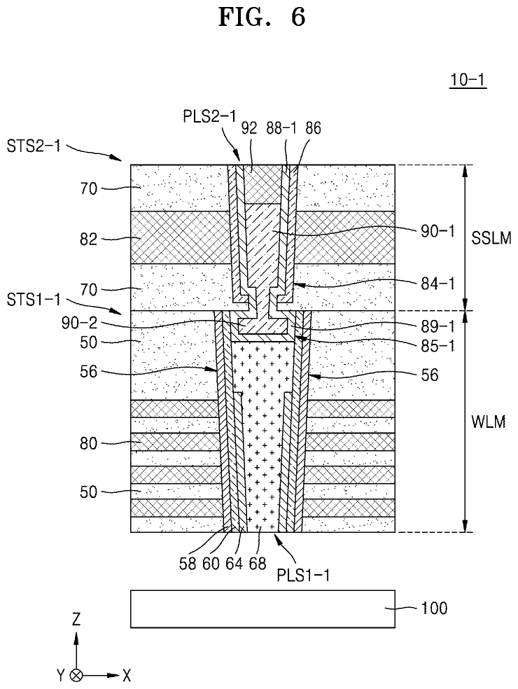

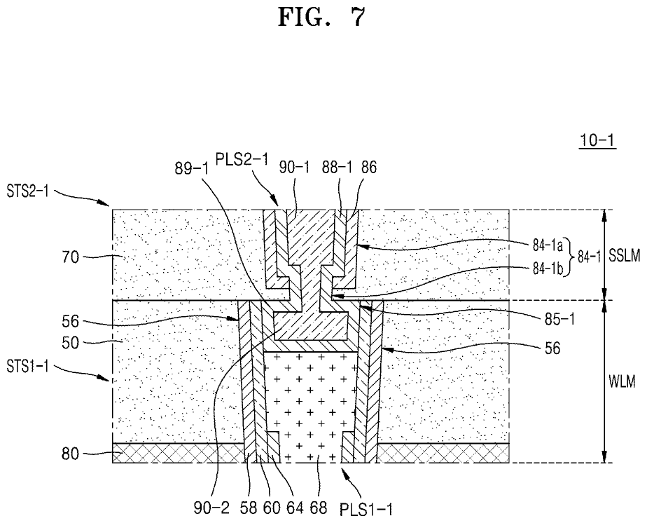

FIG. 6 is a cross-sectional view of a memory cell array of an example vertical type memory device 10-1, according to an embodiment, and FIG. 7 is a partially enlarged view of the example memory device 10-1 shown in FIG. 6.

In detail, FIG. 6 is a cross-sectional view taken along line A-A′ of FIG. 3, and FIG. 7 is a cross-sectional view illustrating a connection relationship between first and second pillar structures PLS1-1 and PLS2-1 of FIG. 6. The vertical type memory device 10-1 of FIGS. 6 and 7 may be substantially the same as the vertical type memory device 10 of FIGS. 4 and 5A, except for a connection pad 89-1. In FIGS. 6 and 7, the description given above with reference to FIGS. 4 to 5B is briefly given or omitted.

The vertical type memory device 10-1 may be formed on the substrate 100. The vertical type memory device 10-1 may include a word line mold WLM formed on the substrate 100 and a first pillar structure PLS1-1 formed in the channel hole 56 inside the word line mold WLM. The word line mold WLM may include a first stack structure STS1-1 including a plurality of cell insulating layers 50 and a first electrode layer 80 located between the cell insulating layers 50. Although shown as including only one first electrode layer 80, the memory device 10-1 May include a plurality of first electrode layers 80 and cell insulating layers 50 sequentially stacked on the substrate 100, in one or more embodiments.

The first pillar structure PLS1-1 may include a first gate insulating layer 58 and a cell channel layer 60 formed on an inner wall of the channel hole 56. The first gate insulating layer 58 and the cell channel layer 60 may be formed inside the channel hole 56. The channel hole 56 may be formed through the first stack structure STS1-1 in the vertical direction (Z direction). The first stack structure STS1-1 may be located on both sidewalls of the channel hole 56.

The first pillar structure PLS1-1 may include a variable resistance layer 64 within the channel hole 56 formed on one side of the cell channel layer 60 (opposite the first gate insulating layer 58) at a height lower than that of the cell channel layer 60 within the channel hole 56 (relative to an upper surface of the substrate 100), and a first filling insulating layer 68 filling the channel hole 56. The variable resistance layer 64 may be formed inside the cell channel layer 60 at a height lower than an upper portion of the channel hole 56. Because the first pillar structure PLS1-1 includes the variable resistance layer 64, the vertical type memory device 10-1 of the inventive concept may be referred to as a variable resistance vertical type memory device.

The first filling insulating layer 68 may not entirely fill the channel hole 56 on the variable resistance layer 64 and the cell channel layer 60. An upper surface of the first filling insulating layer 68 may be lower, in the vertical direction (Z direction), than an upper surface of the channel hole 56. The upper surface of the first filling insulating layer 68 may be lower than upper surfaces of the cell channel layer 60 and the first gate insulating layer 58.

The first pillar structure PLS1-1 may include a connection pad 89-1 formed on the first filling insulating layer 68 inside the channel hole 56. As shown in FIG. 7, the connection pad 89-1 may be formed on an inner wall and upper portion of a recess hole 85-1 located on the first filling insulating layer 68 inside the channel hole 56. The recess hole 85-1 may be deeper than the recess hole 85 of the memory device 10 shown in FIGS. 4 and 5A.

With continued reference to FIGS. 6 and 7, the connection pad 89-1 may be formed on a bottom and both sidewalls of the recess hole 85-1 and on a lower portion of the string select insulating layer 70. The connection pad 89-1 may fill the recess hole 85-1. In some embodiments, the connection pad 89-1 may not fill the recess hole 85-1, and therefore a length thereof may be further increased in the Z direction (the vertical direction) than the connection pad (89 in FIGS. 4 and 5).

The connection pad 89-1 may be referred to as an intermediate pad. Both sides of the connection pad 89-1 may contact the cell channel layer 60 within the channel hole 56. The connection pad 89-1 may include polysilicon doped with impurities or polysilicon without impurities.

The first pillar structure PLS1-1 may include a third filling insulating layer 90-2 filling the recess hole 85-1 on the connection pad 89-1. The third filling insulating layer 90-2 May include the same material as that of a second filling insulating layer 90-1 described below.

The vertical type memory device 10-1 may include a string select line mold SSLM formed on the word line mold WLM and the first pillar structure PLS1-1, and a second pillar structure PLS2-1 formed in a string select line hole 84-1 overlapping the channel hole 56 inside the string select line mold SSLM.

As shown in FIG. 7, the string select line hole 84-1 is shown to overlap a central portion of the channel hole 56, that is, a central portion of the connection pad 89-1, in the Z direction (the vertical direction), but the inventive concept is not limited thereto. In the inventive concept, even when shifted in the X direction or the Y direction from the central portion of the string select line hole 84-1, by including the connection pad 89-1, the second pillar structure PLS2-1 may be easily connected to the first pillar structure PLS1-1, thereby beneficially reducing the need for precise alignment of the string select line hole 84-1 with the channel hole 56.

The string select line mold SSLM may include a second stack structure STS2-1 including the string select insulating layers 70 and the second electrode layer 82 located between the string select insulating layers 70.

The second pillar structure PLS2-1 may include a second gate insulating layer 86 formed on an inner wall of the string select line hole 84-1 and a select channel layer 88-1 formed on one side of the second gate insulating layer 86 and connected to the connection pad 89-1 within the string select line hole 84-1.

The second gate insulating layer 86 and the select channel layer 88-1 may be formed inside the string select line hole 84-1. The second gate insulating layer 86 may be spaced apart from the connection pad 89-1 in the vertical direction (Z direction). The string select line hole 84-1 may be formed through the second stack structure STS2-1 in the vertical direction. The second stack structure STS2 may be located on both sides of the string select line hole 84-1.

As shown in FIG. 7, the string select line hole 84-1 may include a first string select line hole 84-1a located in an upper portion of the string select line hole 84-1, and a second string select line hole 84-1b located in a lower portion of the string select line hole 84-1 below the first string select line hole 84-1a and having a diameter smaller than that of the first string select line hole 84-1a. The second gate insulating layer 86 may be formed on an inner wall of the first string select line hole 84-1a.

As shown in FIG. 7, the select channel layer 88-1 may be formed on the second gate insulating layer 86 inside the first string select line hole 84-1a. The select channel layer 88-1 May be connected to the connection pad 89-1. The select channel layer 88-1 may include polysilicon doped with impurities or polysilicon without impurities. The select channel layer 88-1 may be integrated with the connection pad 89-1. The select channel layer 88-1 may include the same material as that of the connection pad 89-1.

As shown in FIG. 6, the second pillar structure PLS2-1 may include the second filling insulating layer 90-1 filling the string select line hole 84-1 on the select channel layer 88-1. The second filling insulating layer 90-1 may not entirely fill the string select line hole 84-1 on the select channel layer 88-1.

An upper surface of the second filling insulating layer 90-1 may be lower than an upper surface of the string select line hole 84-1 in the vertical direction (Z direction). The upper surface of the second filling insulating layer 90-1 may be lower than upper surfaces of the select channel layer 88-1 and the second gate insulating layer 86 in the vertical direction.

The second pillar structure PLS2-1 may include the bit line pad 92 contacting the select channel layer 88-1 inside the string select line hole 84-1 on the second filling insulating layer 90-1. The bit line pad 92 may correspond to the bit line BL of the example memory cell array MCA shown in FIG. 2. Both sides of the bit line pad 92 may contact the select channel layer 88-1.

Because the vertical type memory device 10-1 as described above includes the first pillar structure PLS1-1 including the connection pad 89-1, the first pillar structure PLS1-1 may be easily connected to the second pillar structure PLS2-1 by using the connection pad 89-1.

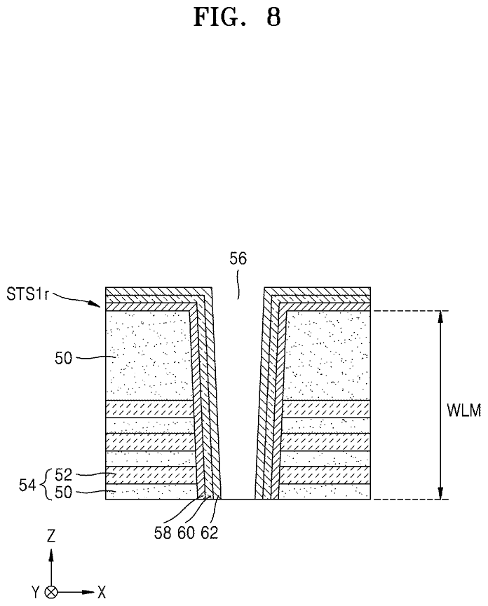

By way of example only and without limitation or loss of generality, FIGS. 8 to 19 are cross-sectional views illustrating intermediate processes in an example method of manufacturing a memory cell array of a vertical type memory device, according to one or more embodiments.

In detail, FIGS. 8 to 19 may be cross-sectional views illustrating a method of manufacturing a memory cell array of the vertical type memory device 10 of FIGS. 4 to FIG. 5B. In FIGS. 8 to 19, the description given above with reference to FIGS. 4 to 5B is briefly given or omitted.

Referring to FIG. 8, a first preliminary stack structure STS1r constituting the word line mold WLM is formed on the substrate (100 of FIG. 4). The first preliminary stack structure STS1r may be formed by stacking a plurality of insulating layers 54. In one or more embodiments, the insulating layers 54 may include one or more cell insulating layers 50 and one or more first sacrificial insulating layers 52 alternately stacked. A cross-sectional thickness of each of the cell insulating layers 50 may be the same as or different from one another. Likewise, a cross-sectional thickness of each of the first sacrificial insulating layers 52 may be the same as or different from one another.

The first preliminary stack structure STS1r may be made by forming the stacked insulating layers 54 on the substrate (100 in FIG. 4). The cell insulating layer 50 may include, for example, silicon oxide, and the first sacrificial insulating layer 52 may include, for example, silicon nitride.

The channel hole 56 is formed inside the first preliminary stack structure STS1r. The channel hole 56 is formed through a central portion of the first preliminary stack structure STS1r in a vertical direction (Z direction). Although not explicitly shown in FIG. 8, the channel hole 56 may expose an upper surface of the substrate (100 in FIG. 4) therethrough. The first gate insulating layer 58, the cell channel layer 60, and the variable resistance material layer 62 are formed on the first preliminary stack structure STS1r and the channel hole 56. The first gate insulating layer 58, the cell channel layer 60, and the variable resistance material layer 62 may be sequentially formed from the inner wall of the channel hole 56. The variable resistance material layer 62 may include the same material as that of the variable resistance layer 64 of FIG. 4, although embodiments of the present inventive concept are not limited thereto.

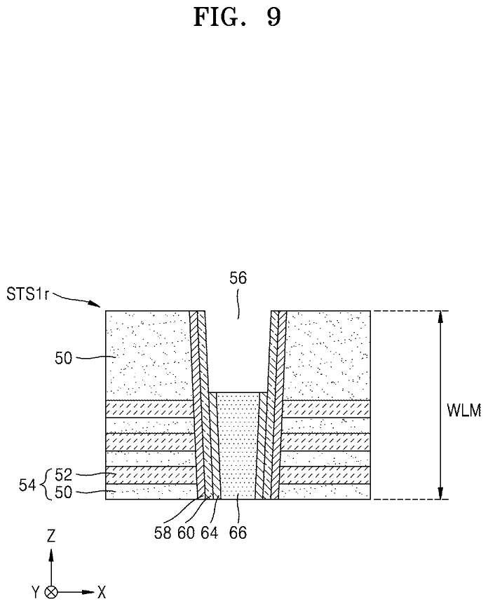

Referring to FIG. 9, after filling the inside of the channel hole 56 on the variable resistance material layer (62 in FIG. 8) with a sacrificial filling material layer, the sacrificial filling material layer and the variable resistive material layer are partially etched to form the variable resistance layer 64 and the sacrificial filling layer 66. When the sacrificial filling material layer and the variable resistance material layer (62 in FIG. 8) are partially etched, the first gate insulating layer 58, the cell channel layer 60, and the variable resistance material layer on the first preliminary stack structure STS1r may be etched.

The sacrificial filling layer 66 may include, for example, a spin on hardmask (SOH) or an amorphous carbon layer (ACL). The SOH layer may include a carbon-based SOH layer or a silicon-based SOH layer. In another embodiment, the sacrificial filling layer 66 may include photoresist or amorphous silicon.

Accordingly, an upper surface of the variable resistance layer 64 and the sacrificial filling layer 66 may be formed to have a height, in the vertical direction, lower than an upper surface of a top portion the channel hole 56 (i.e., an upper rim defining the channel hole 56). A portion of the cell channel layer 60 (e.g., an upper portion) may be exposed inside the channel hole 56. The variable resistance layer 64 may be formed to have a height lower than the surface of the cell channel layer 60.

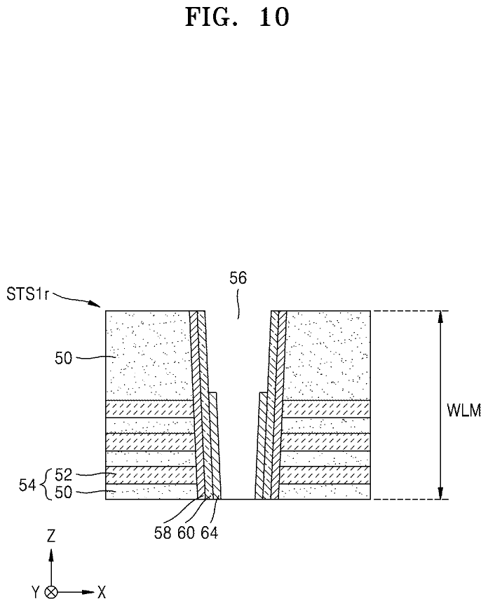

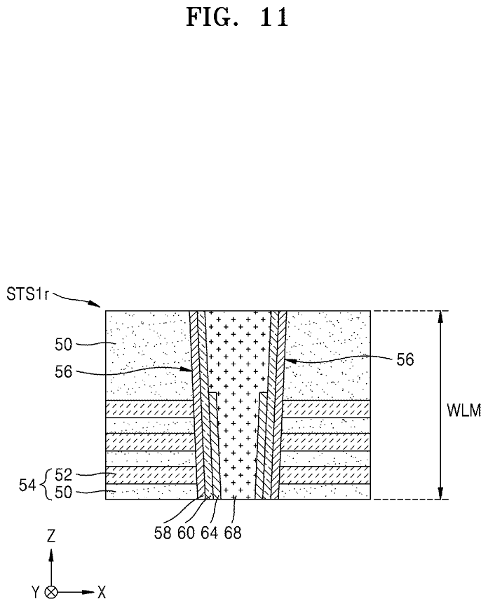

Referring to FIGS. 10 and 11, as shown in FIG. 10, the sacrificial filling layer 66 inside the channel hole 56 may be etched and removed. In this case, the variable resistance layer 64 inside the channel hole 56 may be exposed, along with the upper portion of the cell channel layer 60 (i.e., the portion not covered by the variable resistance layer 64). Subsequently, as shown in FIG. 11, the first filling insulating layer 68 is formed on the variable resistance layer 64 and the cell channel layer 60 in the channel hole 56. The first filling insulating layer 68 may be formed to fill the channel hole 56.

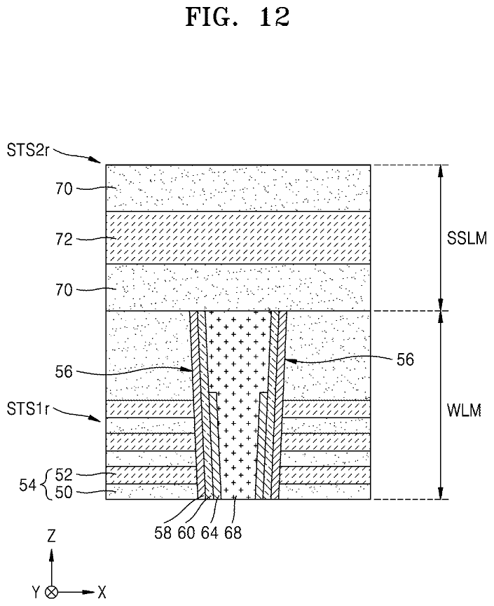

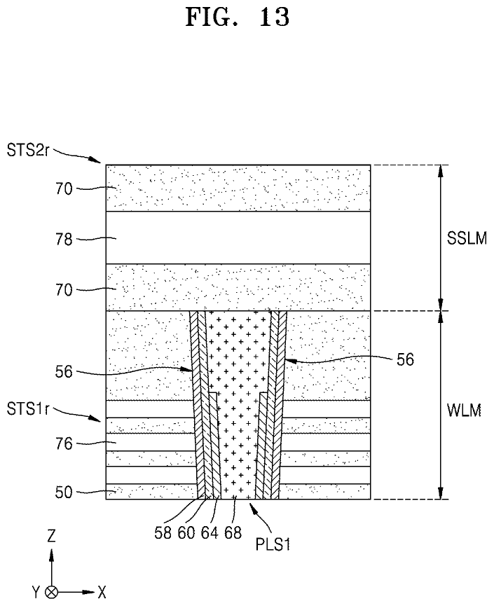

Referring to FIGS. 12 and 13, as shown in FIG. 12, a second preliminary stack structure STS2r constituting the string select line mold SSLM may be formed on the first preliminary stack structure STS1r, the variable resistance layer 64, the cell channel layer 60, and the first filling insulating layer 68.

The second preliminary stack structure STS2r may include a plurality of string select insulating layers 70 and at least one second sacrificial insulating layer 72 located between the string select insulating layers 70. The string select insulating layers 70 may include, for example, silicon oxide, and the second sacrificial insulating layer 72 may include, for example, silicon nitride.

As shown in FIG. 13, a first hole 76 is formed by selectively etching the first sacrificial insulating layer (52 of FIG. 12) constituting the word line mold WLM, between adjacent cell insulating layers 50. The first hole 76 may expose at least a portion of a sidewall of the first gate insulating layer 58.

A second hole 78 may be formed by selectively etching the second sacrificial insulating layer (72 in FIG. 12) constituting the string select line mold SSLM, between adjacent string select insulating layers 70. In some embodiments, the first hole 76 and the second hole 78 May be formed simultaneously (e.g., during the same etch process). The first hole 76 and the second hole 78 may be formed using an etching selectivity of silicon oxide and silicon nitride.

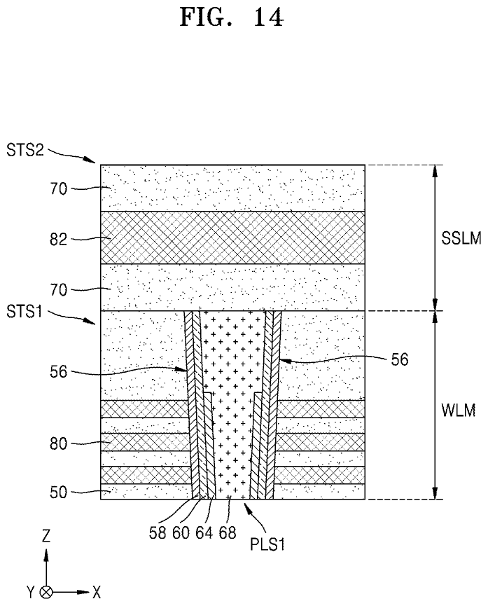

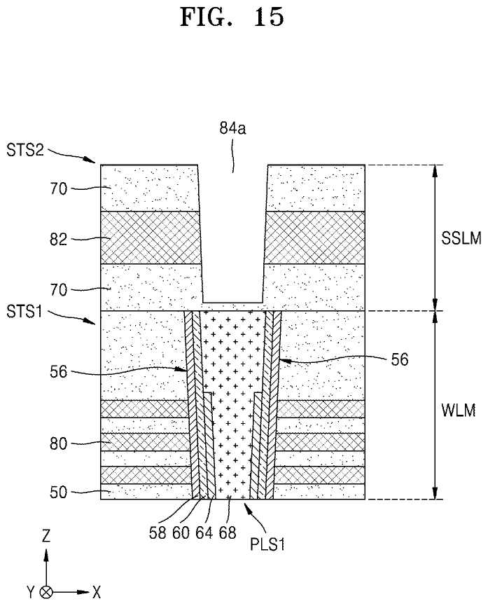

Referring to FIGS. 14 and 15, as shown in FIG. 14, the first hole 76 and the second hole 78 may be filled with a conductive material to form the first electrode layer 80 and the second electrode layer 82, respectively. The first electrode layer 80 filling the first hole 76 may contact the first gate insulating layer 58.

Accordingly, the word line mold WLM may form the first stack structure STS1 including the cell insulating layers 50 and the first electrode layer 80 located between the cell insulating layers 50. The string select line mold SSLM may include the second stack structure STS2 including the string select insulating layers 70 and the second electrode layer 82 located between the string select insulating layers 70.

As shown in FIG. 15, the string select insulating layers 70 and the second electrode layer 82 constituting the string select line mold SSLM are etched to form the first string select line hole 84a. In some embodiments, a portion of the lower string select insulating layer 70 located below the first string select line hole 84a may not be entirely etched. The first string select line hole 84a may vertically overlap (in the Z direction) at least a portion of the channel hole 56, and preferably a central portion of the first string select line hole 84a overlaps a central portion of the channel hole 56 in the vertical direction.

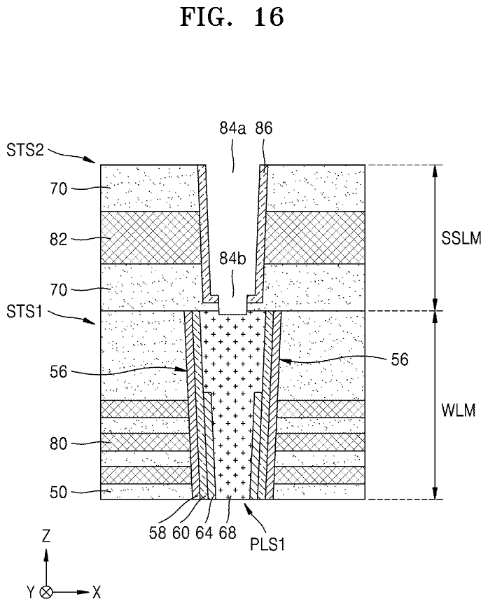

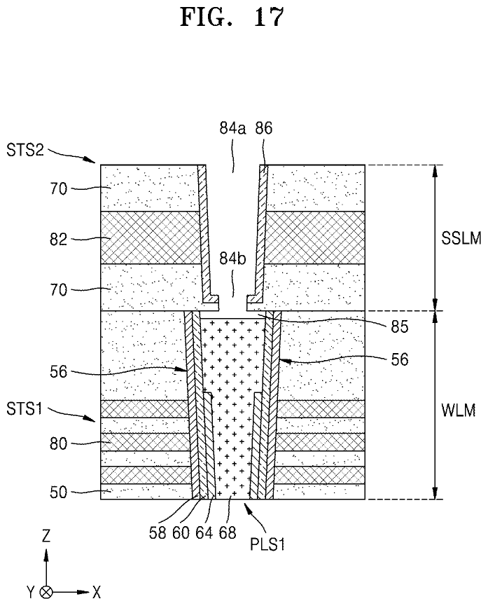

Referring to FIGS. 16 and 17, as shown in FIG. 16, the second gate insulating layer 86 may be formed on the inner wall of the first string select line hole 84a. Subsequently, portions of the second gate insulating layer 86 on a bottom of the first string select line hole 84a and the lower string select insulating layer 70 may be etched to form the second string select line hole 84b. The first string select line hole 84a and the second string select line hole 84b may constitute the string select line hole 84 shown in FIG. 4 and described above.

In some embodiments, a width (i.e., diameter) of the second string select line hole 84b in the first horizontal direction (X direction) may be less than that of the first string select line hole 84a. In some embodiments, when the second string select line hole 84b is formed, a portion of an upper surface of the first filling insulating layer 68 may also be etched.

As shown in FIG. 17, the recess hole 85 is formed in the first filling insulating layer 68 below the first string select line hole 84a and the second string select line hole 84b (between inner sidewalls of the cell channel layer 60). The recess hole 85 may be formed by etching an upper portion of the first filling insulating layer 68.

The recess hole 85 may expose a side surface of the cell channel layer 60 within the channel hole 56. The recess hole 85 may communicate with the first string select line hole 84a and the second string select line hole 84b; that is, the recess hole 85, the second string select line hole 84b and the first string select line hole 84a may form a contiguous opening through the string select line mold SSLM and an upper portion of the word line mold WLM, exposing an upper surface of the first filling insulating layer 68 therethrough.

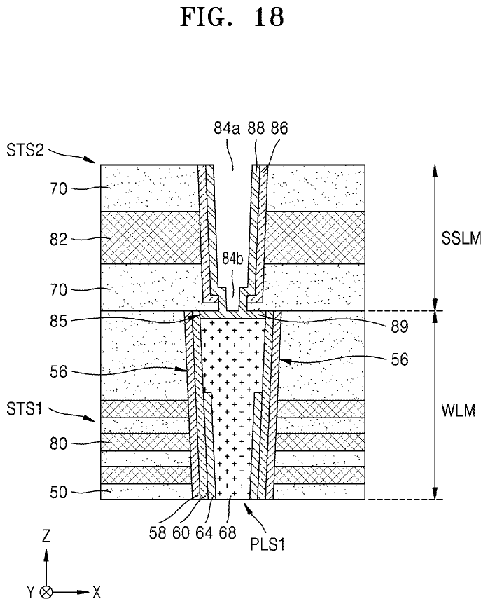

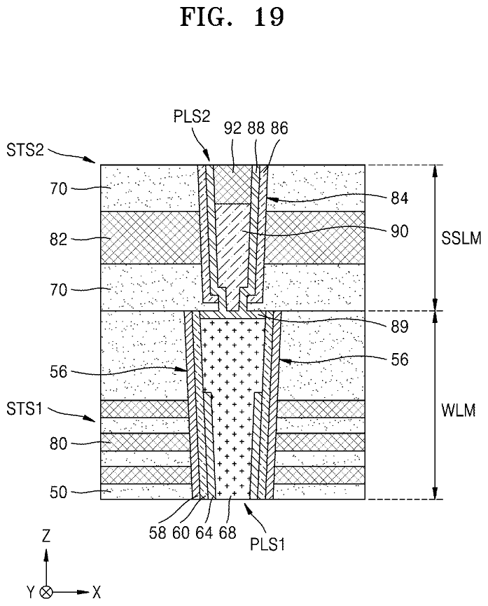

Referring to FIGS. 18 and 19, as shown in FIG. 18, a select channel layer 88 may be formed on the second gate insulating layer 86 on the first string select line hole 84a and the second string select line hole 84b. The connection pad 89 is formed in the recess hole 85.

The select channel layer 88 and the connection pad 89 may be formed simultaneously (i.e., in the same process step). The select channel layer 88 may be integrated with the connection pad 89. The select channel layer 88 may include, for example, polysilicon doped with impurities or polysilicon without impurities. Through this process, the first pillar structure PLS1 including the first gate insulating layer 58, the cell channel layer 60, the variable resistance layer 64, the first filling insulating layer 68, and the connection pad 89 may be formed.

As shown in FIG. 19, the second filling insulating layer 90 and the bit line pad 92 are sequentially formed on the select channel layer 88 within the string select line hole 84 including the first string select line hole 84a and the second string select line hole 84b. Through this process, the second pillar structure PLS2 including the second gate insulating layer 86, the select channel layer 88, and the second filling insulating layer 90 may be formed. The second pillar structure PLS2 may include the bit line pad 92.

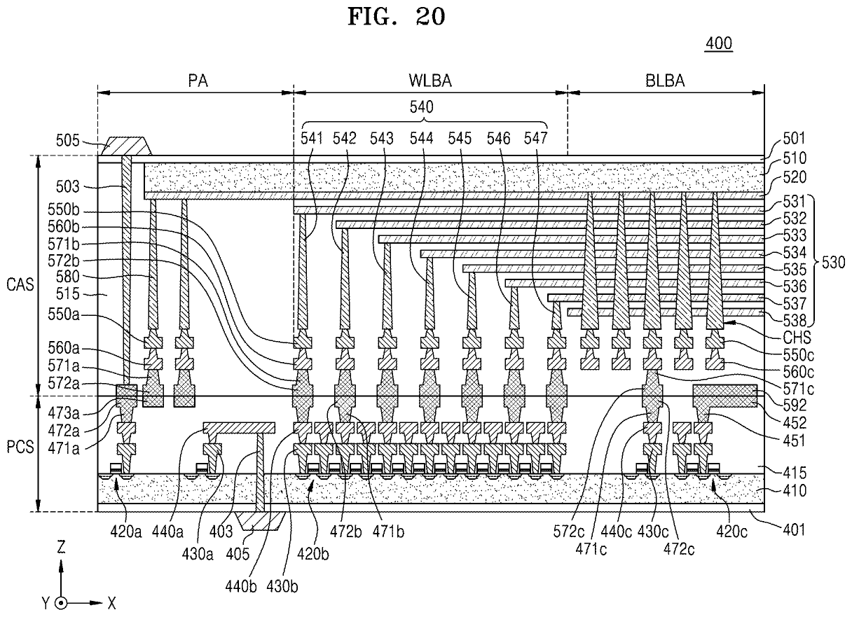

FIG. 20 is a cross-sectional view illustrating at least a portion of an example vertical type memory device 400, according to one or more embodiments.

In an embodiment, the vertical type memory device 400 may have a chip-to-chip (C2C) structure. The structure of the vertical type memory devices 10 and 10-1 described above may be applied to the vertical type memory device 400. In the C2C structure, an upper chip including a cell array structure CAS on a first wafer may be manufactured, a lower chip including a peripheral circuit structure PCS including a peripheral circuit on a second wafer, different from the first wafer, may be manufactured, and thereafter, the upper chip may be connected to (i.e., joined with) the lower chip by a bonding method or alternative wafer joining process.

For example, the bonding method may refer to a method of electrically connecting a bonding metal formed on the uppermost metal layer of the upper chip to a bonding metal formed on the uppermost metal layer of the lower chip. For example, when the bonding metal includes copper (Cu), the bonding method may be a Cu-Cu bonding method, and the bonding metal may include, for example, aluminum (Al) or tungsten (W).

Although bonding of one cell array structure CAS on the peripheral circuit structure PCS is described with reference to FIG. 20, upper chips including a plurality of cell array structures may also be bonded on the peripheral circuit structure PCS.

Each of the peripheral circuit structure PCS and the cell array structure CAS of the vertical type memory device 400 may include an external pad bonding region PA, a word line bonding region WLBA, and a bit line bonding region BLBA.

The peripheral circuit structure PCS may include a first substrate 410, an interlayer insulating layer 415, a plurality of circuit devices 420a, 420b, and 420c formed on the first substrate 410, first metal layers 430a, 430b, and 430c, respectively connected to the circuit devices 420a, 420b, and 420c, and second metal layers 440a, 440b, and 440c formed on the first metal layers 430a, 430b, and 430c.

In an embodiment, the first metal layers 430a, 430b, and 430c may include tungsten having a relatively high resistivity, and the second metal layers 440a, 440b, and 440c may include copper having a relatively low resistivity.

In this specification, only the first metal layers 430a, 430b, and 430c and the second metal layers 440a, 440b, and 440c are shown and described, but the inventive concept is not limited thereto, and at least one metal layer may be further formed on the second metal layers 440a, 440b, and 440c. At least some of the one or more metal layers formed on the second metal layers 440a, 440b, and 440c may include aluminum having a resistivity lower than that of copper forming the second metal layers 440a, 440b, and 440c.

The interlayer insulating layer 415 may be formed on the first substrate 410 to cover the circuit devices 420a, 420b, and 420c, the first metal layers 430a, 430b, and 430c, and the second metal layers 440a, 440b, and 440c, and may include an insulating material, such as silicon oxide or silicon nitride.

Lower bonding metals 471b and 472b may be formed on the second metal layer 440b of the word line bonding region WLBA. In the word line bonding region WLBA, the lower bonding metals 471b and 472b of the peripheral circuit structure PCS may be electrically connected to upper bonding metals 571b and 572b of the cell array structure CAS by a bonding method, and the lower bonding metals 471b and 472b and the upper bonding metals 571b and 572b may include, for example, aluminum, copper, or tungsten.

The cell array structure CAS may provide at least one memory cell block. The cell array structure CAS may include a second substrate 510 and a common source line 520. A plurality of word lines 531 to 538 (collectively, 530) may be stacked on the second substrate 510 in a vertical direction (the Z-axis direction) perpendicular to an upper surface of the second substrate 510 (i.e., a horizontal plane or X and Y directions).

String select lines and a ground select line may be located above and below the word lines 530, and a plurality of word lines 530 may be located between the string select lines and the ground select line.

In the bit line bonding region BLBA, a channel structure CHS may extend in a direction (the Z direction) perpendicular to the upper surface of the second substrate 510 to pass through the word lines 530, the string select lines, and the ground select line. The channel structure CHS may include a gate insulating layer, a cell channel layer, and a filling insulating layer, and the cell channel layer may be electrically connected to a first metal layer 550c and a second metal layer 560c. The channel structure CHS may include the first pillar structure PLS1 and the second pillar structure PLS2 described above.

For example, the first metal layer 550c may be a bit line pad (or bit line contact) and the second metal layer 560c may be a bit line. In an embodiment, the bit line may extend in the second direction (the Y-axis direction) parallel to the upper surface of the second substrate 510. A connection relationship between the channel structure CHS and the first metal layer 550c, that is, the bit line pad, may be the same as described above for the vertical type memory devices 10 and 10-1 of the inventive concept.

In an embodiment, a region in which the channel structure CHS and the bit line 560c are located may be defined as the bit line bonding region BLBA. The bit line 560c may be electrically connected to the circuit devices 420c in the peripheral circuit structure PCS of the bit line bonding region BLBA. For example, the bit line 560c may be connected to upper bonding metals 571c and 572c in the peripheral circuit structure PCS, and the upper bonding metals 571c and 572c may be connected to the lower bonding metals 471c and 472c connected to the circuit devices 420c.

In the word line bonding region WLBA, the word lines 530 may extend in the first direction (the X direction) parallel to the upper surface of the second substrate 510 and may be connected to a plurality of cell contact plugs 541 to 547 (collectively, 540). The word lines 530 may be connected to the cell contact plugs 540 by pads in which at least some of the word lines 530 extend to have different lengths in the first direction (the X direction) to be provided.

The first metal layer 550b and the second metal layer 560b may be sequentially connected to upper portions of the cell contact plugs 540 connected to the word lines 530. The cell contact plugs 540 may be connected to the peripheral circuit structure PCS through the upper bonding metals 571b and 572b of the cell array structure CAS and the lower bonding metals 471b and 472b of the peripheral circuit structure PCS in the word line bonding region WLBA. The cell contact plugs 540 may be electrically connected to the circuit devices 420b in the word line bonding region WLBA of the peripheral circuit structure PCS.

A common source line contact plug 580 may be located in an external pad bonding region PA. The common source line contact plug 580 may include a conductive material, such as metal, a metal compound, or polysilicon, and may be electrically connected to the common source line 520. A first metal layer 550a and a second metal layer 560a may be sequentially stacked on the common source line contact plug 580. For example, a region in which the common source line contact plug 580, the first metal layer 550a, and the second metal layer 560a are arranged may be defined as the external pad bonding region PA.

Lower bonding metals 471a and 472a may be formed in the external pad bonding region PA. In the external pad bonding region PA, the lower bonding metals 471a and 472a of the peripheral circuit structure PCS may be electrically connected to the upper bonding metals 571a and 572a of the cell array structure CAS by a bonding method, and the lower bonding metals 471a and 472a and the upper bonding metals 571a and 572a may include aluminum, copper, or tungsten.

Meanwhile, first and second I/O pads 405 and 505 may be located in the external pad bonding region PA. A lower insulating film or layer 401 covering a lower surface of the first substrate 410 may be formed below the first substrate 410, and the first I/O pad 405 may be formed on the lower insulating film 401.

The first I/O pad 405 may be connected to at least one of the circuit devices 420a, 420b, and 420c arranged in the peripheral circuit structure PCS through a first I/O contact plug 403 formed vertically through the lower insulating film 401 and the first substrate 410, and may be separated from the first substrate 410 by the lower insulating layer 401. In addition, a side insulating layer (not explicitly shown, but implied) may be located between the first I/O contact plug 403 and the first substrate 410 to electrically isolate the first I/O contact plug 403 from the first substrate 410.

An upper insulating layer 501 covering an upper surface of the second substrate 510 may be formed on the second substrate 510, and the second I/O pad 505 may be located on the upper insulating layer 501. The second I/O pad 505 may be connected to at least one of the circuit devices 420a, 420b, and 420c arranged in the peripheral circuit structure PCS through a second I/O contact plug 503 formed vertically through the upper insulating layer 501.

In some embodiments, the second substrate 510 and the common source line 520 may not be located in a region in which the second I/O contact plug 503 is located. In addition, the second I/O pad 505 may not overlap the word lines 530 in the third direction (the Z-axis direction).

The second I/O contact plug 503 may be separated from the second substrate 510 in a direction parallel to an upper surface of the second substrate 510 and may pass through the interlayer insulating layer 515 of the cell array structure CAS, to be connected to the second I/O pad 505.

In some embodiments, the first I/O pad 405 and the second I/O pad 505 may be selectively formed. For example, the vertical type memory device 400 may include only the first I/O pad 405 located on the first substrate 410 or the second I/O pad 505 located on the second substrate 510. Alternatively, the vertical type memory device 400 may include both the first I/O pad 405 and the second I/O pad 505.

In each of the external pad bonding region PA and the bit line bonding region BLBA included in each of the cell array structure CAS and the peripheral circuit structure PCS, a metal pattern of the uppermost metal layer may exist in a dummy pattern, or the uppermost metal layer may be empty.

In the external pad bonding region PA of the vertical type memory device 400, the lower metal patterns 472a and 473a having the same shape as that of the upper metal pattern 572a of the cell array structure CAS may be formed on the uppermost metal layer of the peripheral circuit structure PCS to correspond to the upper metal pattern 572a formed on the uppermost metal layer of the cell array structure CAS. The lower metal pattern 473a formed on the uppermost metal layer of the peripheral circuit structure PCS may not be connected to a separate contact in the peripheral circuit structure PCS.

Similarly, in the external pad bonding region PA, the upper metal pattern 572a having the same shape as that of the lower metal pattern 473a of the peripheral circuit structure PCS may be formed on the upper metal layer of the cell array structure CAS to correspond to the lower metal pattern 473a formed on the uppermost metal layer of the peripheral circuit structure PCS.

The lower bonding metals 471b and 472b may be formed on the second metal layer 440b of the word line bonding region WLBA. In the word line bonding region WLBA, the lower bonding metals 471b and 472b of the peripheral circuit structure PCS may be electrically connected to the upper bonding metals 571b and 572b of the cell array structure CAS by a bonding method.

In addition, in the bit line bonding region BLBA, an upper metal pattern 592 having the same shape as that of the lower metal pattern 452 of the peripheral circuit structure PCS may be formed on the uppermost metal layer of the cell array structure CAS to correspond to the lower metal pattern 452 formed in the uppermost metal layer of the peripheral circuit structures PCS.

A contact may not be formed on the upper metal pattern 592 formed on the uppermost metal layer of the cell array structure CAS. The lower metal pattern 452 of the peripheral circuit structure PCS may be electrically connected to the circuit device 420c through the metal layer 451.

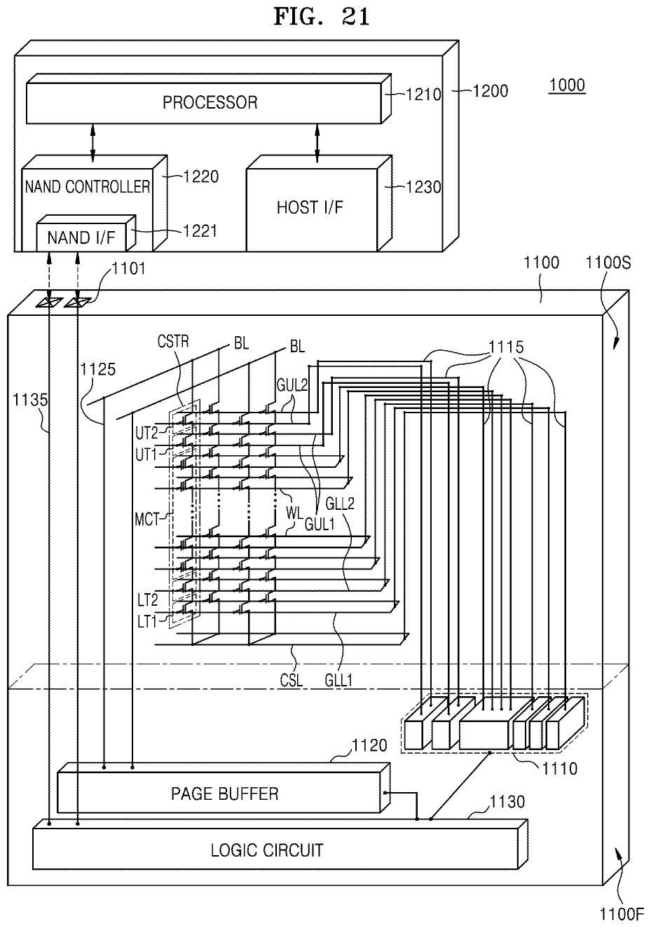

FIG. 21 is a diagram schematically illustrating at least a portion of an example electronic system 1000 including a vertical type memory device according to an embodiment of the inventive concept.

In an embodiment, the electronic system 1000 may include a vertical type memory device 1100 and a controller 1200 electrically connected to the vertical type memory device 1100. The electronic system 1000 may be a storage device including one or a plurality of vertical type memory devices 1100 or an electronic device including the storage device. For example, the electronic system 1000 may include a solid-state drive device (SSD) including at least one vertical type memory device 1100, a universal serial bus (USB), a computing system, a medical device, or a communication device.

The vertical type memory device 1100 may be a nonvolatile memory device. For example, the vertical type memory device 1100 may be a NAND flash memory device including the structure of the vertical type memory devices 10 and 10-1 according to embodiments of the inventive concept described above. The vertical type memory device 1100 may include a first structure 1100F and a second structure 1100S on the first structure 1100F.

In embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including one or more bit lines BL, a common source line CSL, a plurality of word lines WL, first and second gate upper lines GUL1 and GUL2, first and second gate lower lines GLL1 and GLL2, and a plurality of memory cell strings CSTR between corresponding bit lines BL and the common source line CSL.

In the second structure 1100S, the memory cell strings CSTR may include lower transistors LT1 and LT2 adjacent to the common source line CSL, upper transistors UT1 and UT2 adjacent to the bit lines BL, and a plurality of memory cell transistors MCT located between the lower transistors LT1 and LT2 and the upper transistors UT1 and UT2. The number of lower transistors LT1 and LT2 and the number of upper transistors UT1 and UT2 may be variously modified according to embodiments.

In embodiments, the upper transistors UT1 and UT2 may include a string select transistor, and the lower transistors LT1 and LT2 may include a ground select transistor. The gate lower lines GLL1 and GLL2 may be gate electrodes of the lower transistors LT1 and LT2, respectively. The word lines WL may be gate electrodes of the memory cell transistors MCT, and the gate upper lines GUL1 and GUL2 may be gate electrodes of the upper transistors UT1 and UT2, respectively.

The common source line CSL, the gate lower lines GLL1 and GLL2, the word lines WL, and the gate upper lines GUL1 and GUL2 may be electrically connected to the decoder circuit 1110 through a plurality of first connection wirings 1115 extending from the first structure 1100F to the second structure 1100S. The bit lines BL may be electrically connected to the page buffer 1120 through a plurality of second connection wirings 1125 extending from the first structure 1100F to the second structure 1100S.

In the first structure 1100F, the decoder circuit 1110 and the page buffer 1120 May perform a control operation on at least one of the memory cell transistors MCT. The decoder circuit 1110 and the page buffer 1120 may be controlled by the logic circuit 1130.

The vertical type memory device 1100 may communicate with the controller 1200 through one or more I/O pads 1101 electrically connected to the logic circuit 1130. The I/O pads 1101 may be electrically connected to the logic circuit 1130 through an I/O connection wiring 1135 extending from the first structure 1100F to the second structure 1100S.

The controller 1200 may include a processor 1210, a NAND controller 1220, and a host interface (I/F) 1230. According to embodiments, the electronic system 1000 may include a plurality of vertical type memory devices 1100, and in this case, the controller 1200 may control the vertical type memory devices 1100.

The processor 1210 may control the overall operation of the electronic system 1000 including the controller 1200. The processor 1210 may operate according to certain firmware and may access the vertical type memory device 1100 by controlling the NAND controller 1220. The NAND controller 1220 may include a NAND interface (I/F) 1221 that handles communication with the vertical type memory device 1100.

Through the NAND interface 1221, a control command for controlling the vertical type memory device 1100, data to be written to the memory cell transistors MCT of the vertical type memory device 1100, and data to be read from a plurality of memory cell transistors MCT of the vertical type memory device 1100 may be transmitted. The host I/F 1230 may provide a communication function between the electronic system 1000 and an external host. When a control command is received from an external host through the host I/F 1230, the processor 1210 may control the vertical type memory device 1100 in response to the control command.

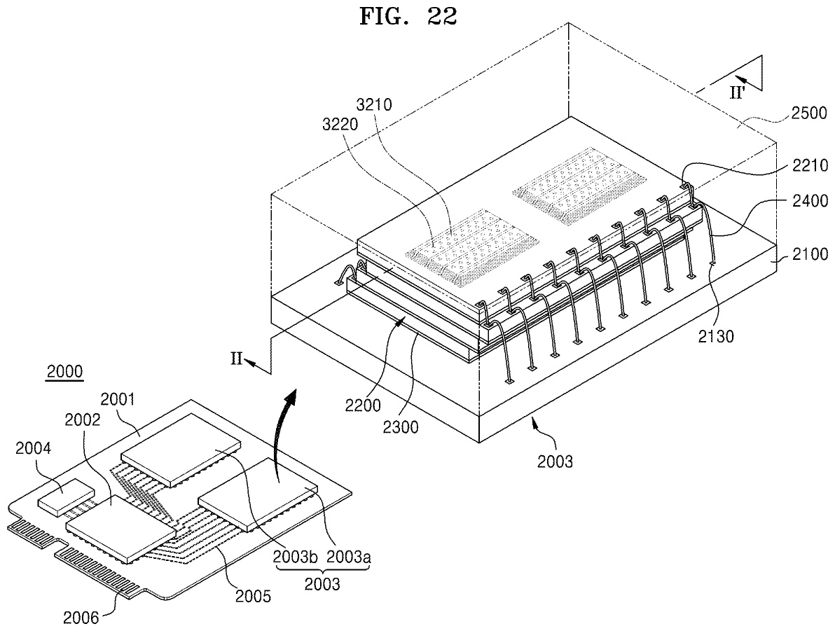

FIG. 22 is a perspective view schematically illustrating an electronic system 2000 including a vertical type memory device, according to an embodiment of the present inventive concept.

In detail, the electronic system 2000 according to an embodiment may include a main board 2001, a controller 2002 mounted on the main board 2001, one or more semiconductor packages 2003, and DRAM 2004. The semiconductor package(s) 2003 and the DRAM 2004 may be connected to the controller 2002 by a plurality of wiring patterns 2005 formed on the main board 2001.

The main board 2001 may include a connector 2006 including a plurality of pins adapted for connection to an external host. The number and arrangement of the pins of the connector 2006 may vary depending on a communication interface between the electronic system 2000 and the external host. In some embodiments, the electronic system 2000 may communicate with the external host according to any one of a number of interfaces (standard or proprietary) such as, for example, a universal serial bus (USB), a peripheral component interconnect express (PCI-Express), a serial advanced technology attachment (SATA), M-Phy for a universal flash storage (UFS), etc. In one or more embodiments, the electronic system 2000 may operate by power supplied from an external host through the connector 2006. The electronic system 2000 May further include a power management integrated circuit (PMIC), not explicitly shown, for distributing power supplied from the external host to the controller 2002 and the semiconductor package(s) 2003.

The controller 2002 may write data to or read data from the semiconductor package(s) 2003, and may improve an operating speed of the electronic system 2000.

The DRAM 2004 may comprise a buffer memory for mitigating a speed difference between the semiconductor package 2003 as a data storage space and the external host. The DRAM 2004 included in the electronic system 2000 may also be configured to operate as a kind of cache memory, and may provide a space for at least temporarily storing data in a control operation for the semiconductor package 2003. When the DRAM 2004 is included in the electronic system 2000, the controller 2002 may further include a DRAM controller for controlling the DRAM 2004 in addition to the NAND controller for controlling the semiconductor package 2003.

The semiconductor package 2003 on the main board 2001 may include first and second semiconductor packages 2003a and 2003b spaced apart from each other. The first and second semiconductor packages 2003a and 2003b may be semiconductor packages each including a plurality of semiconductor chips 2200. Each of the first and second semiconductor packages 2003a and 2003b may include a package substrate 2100, a plurality of semiconductor chips 2200 on the package substrate 2100, an adhesive layer 2300 disposed on a lower surface of each of the semiconductor chips 2200, a connection structure 2400 electrically connecting the semiconductor chips 2200 to the package substrate 2100, and a molding layer 2500 covering (i.e., on) the semiconductor chips 2200 and the connection structure 2400 on the package substrate 2100.

The package substrate 2100 may be a printed circuit board including a plurality of package upper pads 2130. Each of the semiconductor chips 2200 may include one or more I/O pads 2210. The I/O pads 2210 may correspond to the I/O pads 1101 of FIG. 21. Each of the semiconductor chips 2200 may include a plurality of gate stacks 3210 and a plurality of channel structures 3220. Each of the plurality of semiconductor chips 2200 may include at least one of the vertical type memory devices 10 and 10-1 according to embodiments of the inventive concept described above.

In some embodiments, the connection structure 2400 may comprise one or more bonding wires electrically connecting the I/O pads 2210 to the package upper pads 2130. Accordingly, in the first and second semiconductor packages 2003a and 2003b, the semiconductor chips 2200 may be electrically connected to each other by a bonding wire method, and may be electrically connected to the package upper pads 2130 of the package substrate 2100. In embodiments, in the first and second semiconductor packages 2003a and 2003b, the semiconductor chips 2200 May be electrically connected to each other by a connection structure including one or more through-silicon vias (TSV), instead of or in addition to the bonding wire type connection structures 2400.

In some embodiments, the controller 2002 and the semiconductor chips 2200 may be included in a single package. In some embodiments, the controller 2002 and the semiconductor chips 2200 may be mounted on a separate interposer substrate different from the main board 2001, and the controller 2002 may be connected to the semiconductor chips 2200 by a wiring formed on the interposer substrate.

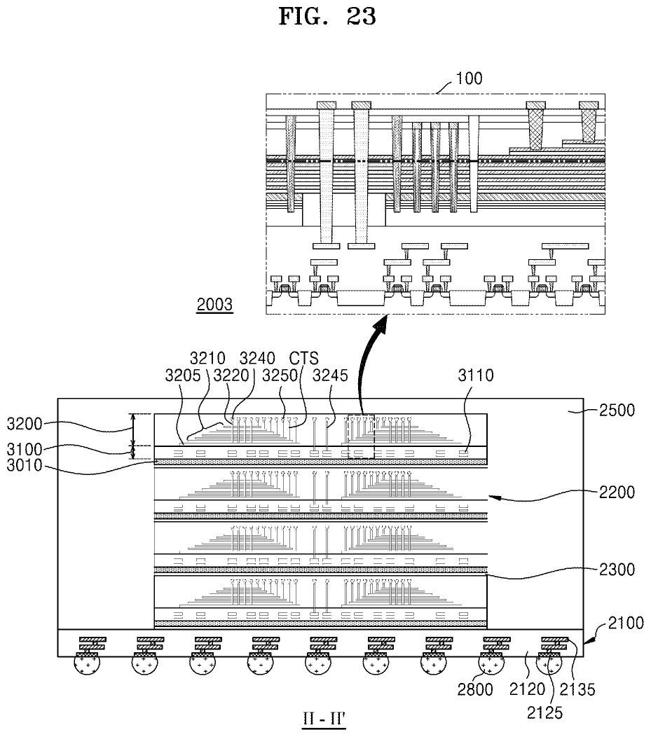

FIG. 23 is a cross-sectional view illustrating semiconductor packages, according to one or more embodiments. In FIG. 23, a configuration taken along line II-II′ of FIG. 22 is shown in detail.

In an embodiment, in the semiconductor package 2003, the package substrate 2100 May be a printed circuit board. The package substrate 2100 may include a package substrate body portion 2120, a plurality of upper pads 2130 arranged on an upper surface of the package substrate body portion 2120 (refer to FIG. 22), and a plurality of internal wirings 2135 electrically connecting the upper pads 2130 to lower pads 2125 inside the package substrate body portion 2120.

The upper pads 2130 may be electrically connected to the connection structures 2400. The lower pads 2125 may be connected to the wiring patterns 2005 on the main board 2001 of the electronic system 2000 illustrated in FIG. 21 through a plurality of conductive connection portions 2800 (e.g., solder balls, conductive bumps, etc.).

Each of the semiconductor chips 2200 may include a semiconductor substrate 3010 and a first structure 3100 and a second structure 3200 sequentially stacked on the semiconductor substrate 3010 in the vertical direction (i.e., perpendicular to a surface of the substrate 3010). The first structure 3100 may include a peripheral circuit region including a plurality of peripheral wirings 3110. The second structure 3200 may include a common source line 3205, a gate stack 3210 on the common source line 3205, a channel structure 3220 passing through the gate stack 3210, and a bit line 3240 electrically connected to the channel structure 3220. In embodiments, each of the semiconductor chips 2200 may include the configuration as that described above for the vertical type memory devices 10 and 10-1 according to illustrative embodiments of the inventive concept described above.

Each of the plurality of semiconductor chips 2200 may include a through-wiring 3245 electrically connected to the peripheral wiring 3110 of the first structure 3100 and extending vertically into the second structure 3200. The through-wiring 3245 may be located outside the gate stack 3210. In other embodiments, the semiconductor package 2003 may further include a through-wiring passing through the gate stack 3210. Each of the semiconductor chips 2200 May further include the I/O pad (2210 in FIG. 22) electrically connected to the peripheral wirings 3110 of the first structure 3100.

It will be understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Spatially descriptive terms such as “above,” “below,” “upper” and “lower” may be used herein to indicate a position of elements, structures or features relative to one another as illustrated in the figures, rather than absolute position. Thus, the semiconductor device may be otherwise oriented (e.g., rotated 90 degrees or at other orientations), and the spatially relative descriptions used herein may be interpreted accordingly.

It will also be understood that when an element such as a layer, region or substrate is referred to as being “atop,” “above,” “on” or “over” another element, it is broadly intended that the element be in direct contact with the other element or intervening elements can also be present. In contrast, when an element is referred to as being “directly on” or “directly over” another element, it is intended that there are no intervening elements present. Likewise, it should be appreciated that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

While the inventive concept has been particularly shown and described with reference to embodiments thereof, it will be understood that various changes in form and details may be made therein without departing from the spirit and scope of the following claims.

What is claimed is:

1. A vertical type memory device, comprising:
a word line mold on at least a portion of a substrate;
a first pillar structure in a channel hole within the word line mold;
a string select line mold on the word line mold and the first pillar structure; and
a second pillar structure in a string select line hole inside the string select line mold, the string select line hole overlapping at least a portion of the channel hole in a vertical direction perpendicular to an upper surface of the substrate,
wherein the first pillar structure includes a first gate insulating layer and a cell channel layer on an inner wall of the channel hole, a variable resistance layer on one side of the cell channel layer, an upper surface of the variable resistance layer being at a height lower than a height of an upper surface of the cell channel layer in the channel hole, a first filling insulating layer in the channel hole, and a connection pad in an upper portion of the first filling insulating layer inside the channel hole, and
wherein the second pillar structure includes a second gate insulating layer on an inner wall of the string select line hole, a select channel layer on one side of the second gate insulating layer within the string select line hole and connected to the connection pad, and a second filling insulating layer at least partially filling the string select line hole on the select channel layer.

2. The vertical type memory device of claim 1, wherein the word line mold includes a first stack structure including a plurality of cell insulating layers and a first electrode layer between the plurality of cell insulating layers.

3. The vertical type memory device of claim 2, wherein the plurality of cell insulating layers comprises at least an uppermost cell insulating layer and a lower cell insulating layer that is between the uppermost cell insulating layer and the substrate, and a cross-sectional thickness of the uppermost cell insulating layer is greater than a cross-sectional thickness of the lower cell insulating layer.

4. The vertical type memory device of claim 1, wherein sidewalls of the connection pad contact the cell channel layer within the channel hole.

5. The vertical type memory device of claim 1, wherein the string select line mold includes a second stack structure including a plurality of string select insulating layers and a second electrode layer between the plurality of string select insulating layers.

6. The vertical type memory device of claim 1, wherein the second gate insulating layer is spaced apart from the connection pad in the vertical direction.

7. The vertical type memory device of claim 1, wherein the string select line hole includes a first string select line hole and a second string select line hole, the second string select line hole located below the first string select line hole and having a smaller width relative to the first string select line hole.

8. The vertical type memory device of claim 1, wherein a bit line contacting the select channel layer is further provided inside the string select line hole on the second filling insulating layer.

9. A vertical type memory device, comprising:
a word line mold on at least a portion of a substrate;
a first pillar structure in a channel hole within the word line mold;
a string select line mold on the word line mold and the first pillar structure; and
a second pillar structure in a string select line hole within the string select line mold, the second pillar structure overlapping the first pillar structure,
wherein the first pillar structure includes a first gate insulating layer and a cell channel layer on an inner wall of the channel hole, a variable resistance layer that is lower than the cell channel layer, a first filling insulating layer in the channel hole, a recess hole in the channel hole, and a connection pad in the recess hole, a lower surface of the connection pad being lower than an upper surface of the first gate insulating layer, and
the second pillar structure includes a second gate insulating layer on an inner wall of the string select line hole, a select channel layer on one side of the second gate insulating layer within the string select line hole and connected to the connection pad, and a second filling insulating layer in the string select line hole on the select channel layer.

10. The vertical type memory device of claim 9, wherein the word line mold includes a first stack structure including a plurality of cell insulating layers and a first electrode layer between the plurality of cell insulating layers.

11. The vertical type memory device of claim 10, wherein a cross-sectional thickness of an uppermost cell insulating layer, among the plurality of cell insulating layers, is greater than a cross-sectional thickness of a lower cell insulating layer.

12. The vertical type memory device of claim 9, wherein the string select line mold includes a second stack structure including a plurality of string select insulating layers and a second electrode layer between the plurality of string select insulating layers.

13. The vertical type memory device of claim 9, wherein sidewalls of the connection pad contact the cell channel layer within the channel hole.

14. The vertical type memory device of claim 9, wherein the string select line hole includes a first string select line hole and a second string select line hole, the second string select line hole being below the first string select line hole and having a smaller width relative to a width of the first string select line hole, and the second gate insulating layer is spaced apart in the vertical direction from the connection pad.

15. The vertical type memory device of claim 9, wherein a bit line contacting the select channel layer is further provided within the string select line hole on the second filling insulating layer.

16. A vertical type memory device, comprising:
a word line mold on a substrate;
a first pillar structure in a channel hole within the word line mold;
a string select line mold on the word line mold and the first pillar structure; and
a second pillar structure in a string select line hole within the string select line mold, the second pillar structure at least partially overlapping the first pillar structure in a vertical direction perpendicular to an upper surface of the substrate,
wherein the first pillar structure includes a first gate insulating layer and a cell channel layer on an inner wall of the channel hole, a variable resistance layer on one side of the cell channel layer at a height lower than a height of the cell channel layer in the channel hole, a first filling insulating layer in the channel hole, a recess hole in the channel hole, the recess hole being lower than an upper surface of the first gate insulating layer and the cell channel layer, and a connection pad on an inner wall of the recess hole and an upper portion of the recess hole, and
wherein the second pillar structure includes a second gate insulating layer on an inner wall of the string select line hole, a select channel layer on one side of the second gate insulating layer within the string select line hole and connected to the connection pad, and a second filling insulating layer in the string select line hole on the select channel layer.

17. The vertical type memory device of claim 16, wherein a third filling insulating layer is further provided in the recess hole on the connection pad, and the third filling insulating layer is connected to the second filling insulating layer.

18. The vertical type memory device of claim 16, wherein the word line mold includes a first stack structure including a plurality of cell insulating layers and a first electrode layer between the plurality of cell insulating layers, and
the string select line mold includes a second stack structure including a plurality of string select insulating layers and a second electrode layer between the plurality of string select insulating layers.

19. The vertical type memory device of claim 16, wherein sidewalls of the connection pad contact the cell channel layer within the channel hole.

20. The vertical type memory device of claim 16, wherein a bit line contacting the select channel layer is further provided within the string select line hole on the second filling insulating layer.
